(19) United States
(12) Patent Application Publication
(10) Pub. No.: US 2013/0271897 A1
(43) Pub. Date: Oct. 17, 2013

(54) Functional case for wireless devices

(71) Applicants: Jamie Limber, Tempe, AZ (US); Jay C. Cronin, Fort Collins, CO (US); William D. Hinz, II, Fort Collins, CO (US)

(72) Inventors: Jamie Limber, Tempe, AZ (US); Jay C. Cronin, Fort Collins, CO (US); William D. Hinz, II, Fort Collins, CO (US)

(21) Appl. No.: 13/506,328

(22) Filed: Apr. 12, 2012

(51) Int. Cl. H05K 7/00

(52) U.S. Cl. 361/679.01

(57) ABSTRACT

A jacket for protecting wireless communication devices having a two piece cover, having a front cover and a rear cover, the front cover having a shaped body with a front cover lip; the rear cover having a shaped rear body with a rear cover lip; and an electronic circuit comprising at least one power supply electronically connected to at least one microcontroller, at least one signal input mechanism from the wireless communication device to the microcontroller, and at least one output mechanism from the microcontroller that is discernible by the user, wherein the electronic circuit operates in such a way that it is capable of performing its own operations independently of the wireless communications device or in combination with the wireless communications device and the output device is a decorative lightable display.

### FIELD OF THE INVENTION

The present invention relates to a device and method for a cell phone jacket designed to cover, protect and add functionality to a variety of wireless devices, such as, but not limited to, cellular phones.

### BACKGROUND OF INVENTION

It is well known that there are a vast variety of wireless communication devices which feature a wide range of functions. Some wireless communication devices feature limited functions, storage or processing power. Previously, if a user wanted gain new functionality they were forced to purchase a new wireless communication device.

Additionally, a user may not wish to retain all functionality at all times. For example, a user may want additional storage space on their device at work but may not want the bulk of increased storage when at home or out for the evening.

A small number of devices have attempted to add functionality to wireless communication devices.

U.S. Pat. No. 20110077061 describes a device in which interchangeable trays, such as a credit card or makeup holder, can be installed on a case for a wireless communication device such as a cell phone or personal digital assistant (PDA). This device is extremely limited in its functionality as it contains no independent processing ability or ability to communicate with the wireless communication device.

U.S. Pat. No. 20100210308 describes a device in which a series of jackets add operability to a base cellular phone via a direct wired connection. This device suffers from several problems. First, this jacket requires users to purchase a specific cell phone module designed for interoperability. Second, the jacket relies on a proprietary direct-wired connection where specific connections control specific functions. Finally, to exchange functionality the entire jacket must be removed from the wireless device and exchanged for another jacket which must then be installed.

The present invention and method provides a solution to the above problems by allowing a user to interchange a variety of functional peripherals within one jacket. Said peripherals communicate with the wireless communication device through wireless radio or a standardized direct connection such as a Universal Serial Bus. These improvements allow users to operate the device with a variety of wireless communication devices, not just those designed specifically for interoperability. Additionally, a user can choose which, if any functionality, to add to their device at a given time.

### SUMMARY OF THE INVENTION

It is an object of the present invention to provide a device and method for a jacket covering for a variety of wireless communication devices, such as, but not limited to, cellular phones.

It is a further object of the present invention to provide a device and method for a series of jackets that communicate and add functionality to a variety of wireless communication devices.

The novel features that are considered characteristic of the invention are set forth with particularity in the appended claims. The invention itself, however, both as to its structure and its operation together with the additional object and advantages thereof will best be understood from the following description of the preferred embodiment of the present invention when read in conjunction with the accompanying drawings. Unless specifically noted, it is intended that the words and phrases in the specification and claims be given the ordinary and accustomed meaning to those of ordinary skill in the applicable art or arts. If any other meaning is intended, the specification will specifically state that a special meaning is being applied to a word or phrase. Likewise, the use of the words “function” or “means” in the Description of Preferred Embodiments is not intended to indicate a desire to invoke the special provision of 35 U.S.C. §112, paragraph 6 to define the invention. To the contrary, if the provisions of 35 U.S.C. §112, paragraph 6, are sought to be invoked to define the invention(s), the claims will specifically state the phrases “means for” or “step for” and a function, without also reciting in such phrases any structure, material, or act in support of the function. Even when the claims recite a “means for” or “step for” performing a function, if they also recite any structure, material or acts in support of that means of step, then the intention is not to invoke the provisions of 35 U.S.C. §112, paragraph 6. Moreover, even if the provisions of 35 U.S.C. §112, paragraph 6, are invoked to define the inventions, it is intended that the inventions not be limited only to the specific structure, material or acts that are described in the preferred embodiments, but in addition, include any and all structures, materials or acts that perform the claimed function, along with any and all known or later-developed equivalent structures, materials or acts for performing the claimed function.

### BRIEF DESCRIPTION OF THE DRAWINGS

The invention will be more fully understood by referring to the following Detailed Description of Specific Embodiments in conjunction with the Drawings, of which:

FIG. 1 is a perspective view of the present invention;

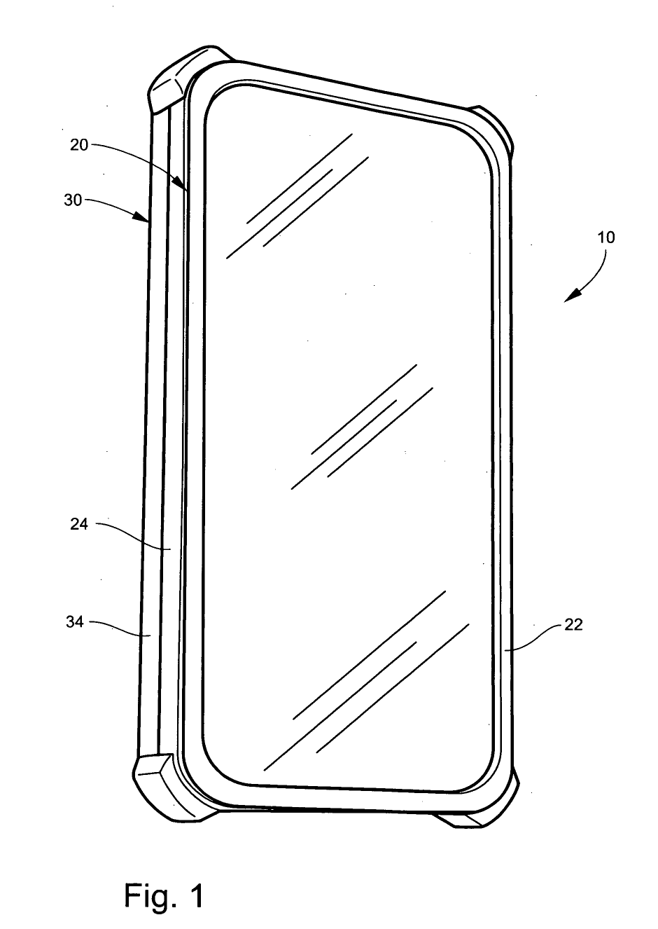

FIG. 2 is a reverse perspective view of the present invention;

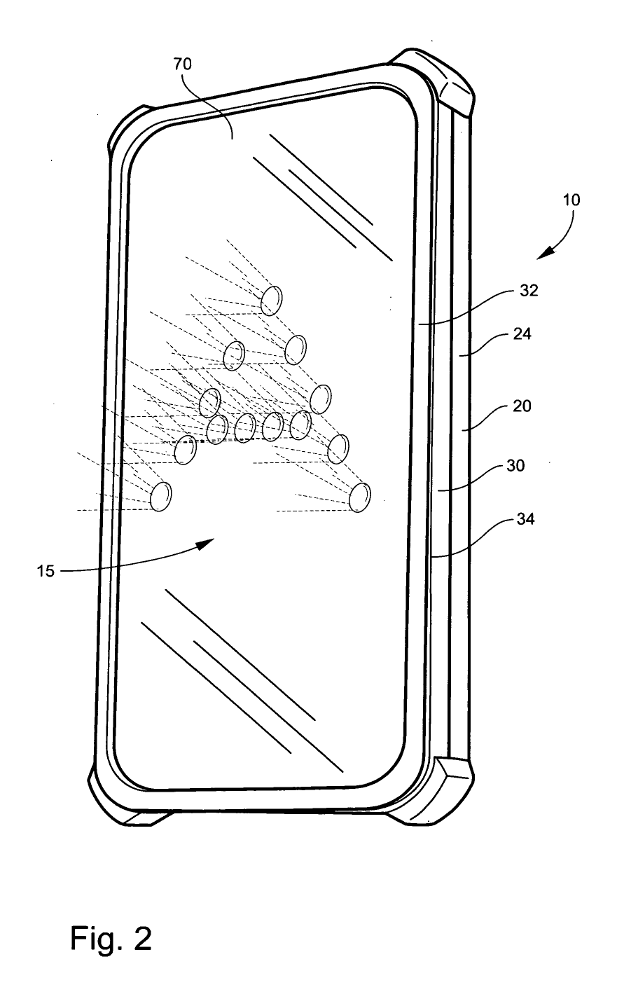

FIG. 3 is an exploded view of one embodiment of the present invention; and

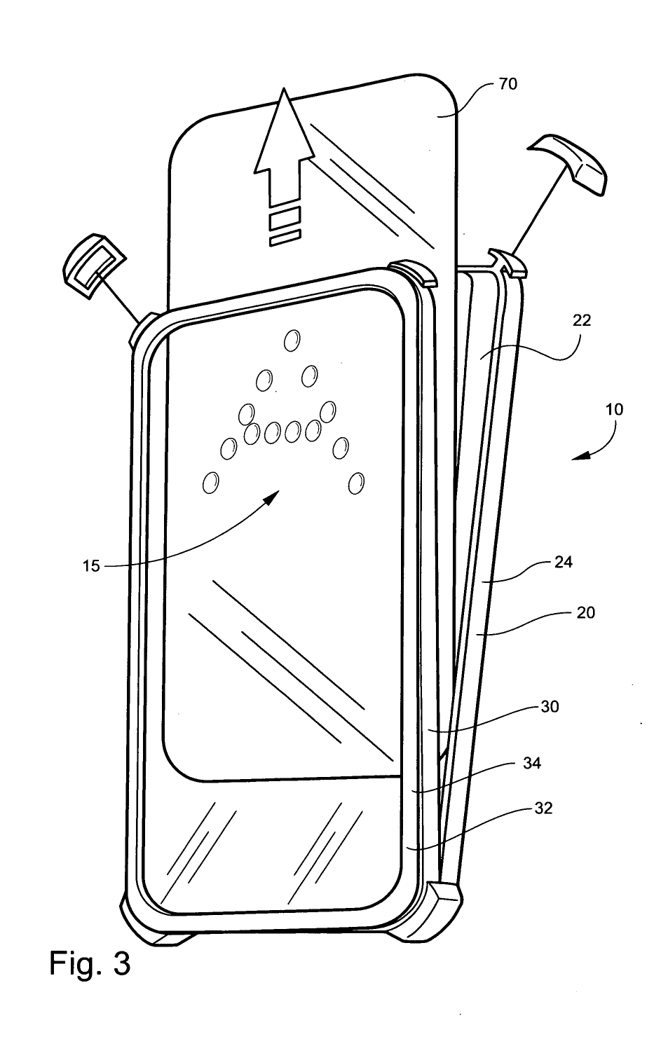

FIG. 4 is a block diagram of the circuit of the present invention.

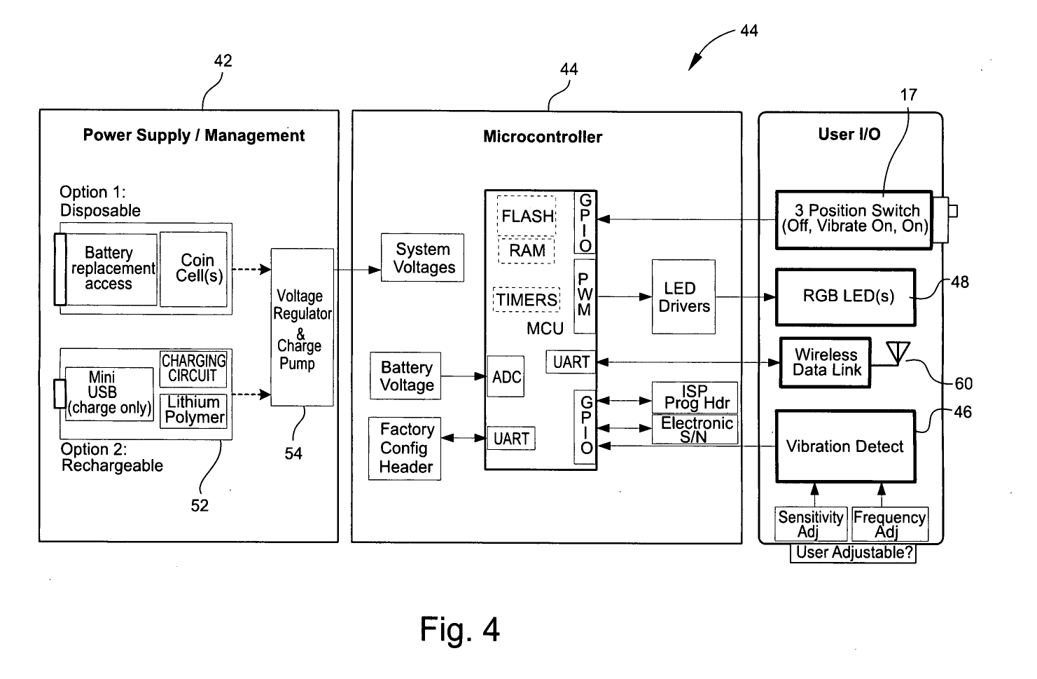

### DETAILED DESCRIPTION OF SPECIFIC EMBODIMENTS

The present invention is a functional protective jacket 10 for a variety of wireless devices 1 such as, but not limited to, cellular phones, tablet computers and the like.

The preferred protective jacket 10 comprises at least two pieces of a protective, rigid or semi-rigid skeleton that surrounds the perimeter edge of the wireless device 1. In a preferred embodiment there is a front cover 20 and a rear cover 30. The front and rear covers, 20 and 30, are adapted to snugly fit a prespecified wireless communications device 1. While the preferred protective jacket 10 comprises at least two pieces of a protective, rigid or semi-rigid skeleton that surrounds the perimeter edge of the wireless device 1, unitary protective jackets 10 are also considered to fall within the scope of the present invention.

The preferred front cover 20 comprises a shaped front body 22 having a front cover lip 24 that is sized to fit around the periphery of the prespecified wireless communications device 1. The preferred rear cover 30 comprises a shaped rear body 32 having a rear cover lip 34 that is sized to fit around the periphery of the prespecified wireless communications device 1. Preferably, the front cover lip 24 and the rear cover lip 34, when the front cover 20 and rear cover 30 are attached to the wireless communications device 1, are located in close proximity to each other.

The jacket 10 further comprises an electronic circuit 40 that is capable of interacting with the protected wireless communications device 1. Preferably the electronic circuit 40 comprises at least one power supply 42, such as a battery electronically connected to at least one microcontroller 44, at least one signal input mechanism 46 from the wireless communication device to the microcontroller 44, such as, but not limited to, wireless radio transmitter/receiver, vibration detector or the like, and at least one output mechanism 48 from the microcontroller 44 that is discernible by the user. The electronic circuit 40 operates in such a way that it is capable of performing its own operations independently of the wireless communications device 1.

Preferably the power supply 42 are small batteries. Small disposable batteries have the benefit of being low cost, have no charge heat and reduce the complexity of circuit 40. The detriment of disposable batteries are they have a shorter run time and required the user have access in order to replace them. Rechargeable batteries have the benefit of a longer run time and do not require user access. Rechargeable batteries have the detriment of higher cost, charge heating and require more complexity to circuit 40. According to the present invention the most preferred battery for the power supply 42 are rechargeable batteries.

Accordingly, in the preferred circuit 42 there may be a battery recharge circuit 52 electronically accessable via a plug port, such as a mini-USB port, or the like.

Interposed between the power supply 42 and the microcontroller 44 may be additional power control/maintenance circuitry 54, such as a voltage regulator, a charge pump, a joule thief or the like. The addition of a charge pump or joule thief, or other like circuits, greatly extends the run time of the power supply thereby reducing the frequency of either battery replacement or recharge.

The preferred microcontroller 44 should have: a low power consumption requirement; be capable of pulse width modulation; a timer function; capable of A/D conversion to monitor battery level/charge status; have at least one general purpose I/O (GPIO) for switches and sensors; be in system programmable; and may include electronic S/N.

In one embodiment, the preferred means for signal input mechanism 46 is a vibration detector. In another embodiment, the preferred means for inputting a signal 46 is a radio frequency receiver. In yet another embodiment, the preferred means for inputting a signal 46 is a magnetic field detector.

The output mechanism 48 can be a number of different devices, such as, but not limited to, cameras, lenses, lights, displays, indicia, projectors, speakers, or other addition electronic components. One preferred output mechanism 48 is a light source, such as a Light Emitting Diode (LED), more preferably a Red Green Blue (RGB) LED.

In one embodiment, the circuit 40 may also include a manual switch 17 such as a 3 position switch (on, off, detect on). The manual switch 17 is preferably accessible from the external surface of the jacket 10, allows a user to switch between display area in a fully on mode, display area in a fully off mode, or display area ready for activation by the electronic circuit 40 detecting a remote signal sent from the wireless communications device 1.

In one embodiment, the circuit 40 may also include a wireless data link 60 for remotely reprogramming the circuit 40.

In use, the circuit 40 is programmed such that, when attached to the wireless communications device 1, the jacket 20 begins in an off state. The user may elect to manually turn on the circuit 40 using switch 50. In this on state, the circuit 40 functions as programmed by activating the output mechanism 48.

Alternately the user may elect to turn the circuit 40 to a detect/on state. In this state, the circuit is in a low power use mode until a change of state is detected at the signal input mechanism 46. In one embodiment, when the wireless communications device 1 activates its buzzer, this vibration is detected at the signal input mechanism 46 thereby turning on the circuit 40, which then activates the output mechanism 48 as programmed. In another embodiment, the wireless communications device 1 may send out a radio frequency signal that is detected by the signal input mechanism 46 thereby turning on the circuit 40, which then activates the output mechanism 48 as programmed. In yet another embodiment, the wireless communications device 1 may send out a magnetic signal that is detected by the signal input mechanism 46 thereby turning on the circuit 40, which then activates the output mechanism 48 as programmed.

In an alternate embodiment of the jacket 10, the jacket 10 uses a direct wired connection instead of a wireless radio transmitter/receiver for communicating between the electronic circuit 40 and the wireless communication device 1.

In yet another embodiment of the jacket 10, the jacket 10 includes one or more buttons, switches, or touch sensitive areas that can be operated by the user to control various functions of the jacket 10, the electronic circuit 40, and/or various computer applications resident in the computer.

In a preferred embodiment, the jacket 10 includes at least one display area 15 such as, but not limited to, a Liquid Crystal Display (LCD) or an array of Light Emitting Diodes (LEDs), for displaying images, lights, animations, application data or other indicia. The at least one display area 15 is electronically connected to the electronic circuit 40 such that the electronic circuit 40 controls the at least one display area 15. Further, in this embodiment, the display area may be a decorative display area (one that does not function other that as decoration; e.g. does not also function as a flashlight).

In an alternate embodiment, at least one of the LEDs also functions as a light detector or photo sensor. In this versions, the at least one LED may either active or deactivate a function of the microcontroller 42.

Preferred embodiments of the jacket 10 include a series of openings, coverings or covered openings that allow a user to access and manipulate buttons or ports located around the perimeter edge of the wireless communication device 1 while still providing a protective continuous structure around the perimeter edge of the wireless communication device 1.

In an alternate embodiment, the circuit 40 of the present invention is contained within a separate section or card 70 that is removable from the jacket 10. In this embodiment, the rear cover 30, or rear section of a unitary jacket, includes an aperture that is sized to fit, but snugly hold the card 70 in place when the wireless communications device 1 is in the jacket 10. Thus, the card may be of any suitable shape as long as it also contains circuit 40, such as a circular shape, rectangular shape, or the like.

The preferred embodiment of the invention is described above in the Drawings and Description of Preferred Embodiments. While these descriptions directly describe the above embodiments, it is understood that those skilled in the art may conceive modifications and/or variations to the specific embodiments shown and described herein. Any such modifications or variations that fall within the purview of this description are intended to be included therein as well. Unless specifically noted, it is the intention of the inventor that the words and phrases in the specification and claims be given the ordinary and accustomed meanings to those of ordinary skill in the applicable art(s). The foregoing description of a preferred embodiment and best mode of the invention known to the applicant at the time of filing the application has been presented and is intended for the purposes of illustration and description. It is not intended to be exhaustive or to limit the invention to the precise form disclosed, and many modifications and variations are possible in the light of the above teachings. The embodiment was chosen and described in order to best explain the principles of the invention and its practical application and to enable others skilled in the art to best utilize the invention in various embodiments and with various modifications as are suited to the particular use contemplated.

What is claimed is:

1. A device for protecting wireless communication devices comprising:
a. a two piece cover, having a front cover and a rear cover,
i. the front cover having a shaped body with a front cover lip;
ii. the rear cover having a shaped rear body with a rear cover lip; and
b. an electronic circuit comprising at least one power supply electronically connected to at least one microcontroller, at least one signal input mechanism from the wireless communication device to the microcontroller, and at least one output mechanism from the microcontroller that is discernible by the user, wherein the electronic circuit operates in such a way that it is capable of performing its own operations independently of the wireless communications device or in combination with the wireless communications device.

2. The device according to claim 1 wherein the output device is a decorative lightable display.

3. The device according to claim 1 wherein the circuit further comprises an additional power/control/maintenance circuitry interposed between the at least one power supply and the at least one microcontroller.

4. The device according to claim 1 wherein the microcontroller has a low power consumption, is capable of pulse width modulation, has a timer function, is capable of A/D conversion to monitor batter level/charge status, has at least one general purpose In/Out for switches and sensors and is in system programmable.

5. The device according to claim 1 wherein at least one of the at least one signal input mechanism is selected from the group consisting of a vibration detector, a radio frequency receiver and a magnetic field detector.

6. The device according to claim 1 wherein the output mechanism is selected from at least one of the group consisting of cameras, lenses, LEDs, lights, displays, indicia, projectors, speakers, or other addition electronic components.

7. The device according to claim 1 wherein the electronic circuit further comprises a three position switch for on, off and detect on.

8. The device according to claim 1 wherein the electronic circuit further comprises a wireless data link for remotely reprogramming the circuit.

9. The device according to claim 1 wherein the output device is an LED and the LED further functions as a light detector or photo sensor.

10. The device according to claim 1 wherein the electronic circuit is contained within a piece that is separate from the front cover and the rear cover and is attachable to either the front cover or the rear cover.

11. The device according to claim 2 wherein the electronic circuit is contained within a piece that is separate from the front cover and the rear cover and is attachable to either the front cover or the rear cover.

12. The device according to claim 3 wherein the electronic circuit is contained within a piece that is separate from the front cover and the rear cover and is attachable to either the front cover or the rear cover.

13. The device according to claim 4 wherein the electronic circuit is contained within a piece that is separate from the front cover and the rear cover and is attachable to either the front cover or the rear cover.

14. The device according to claim 5 wherein the electronic circuit is contained within a piece that is separate from the front cover and the rear cover and is attachable to either the front cover or the rear cover.

15. The device according to claim 6 wherein the electronic circuit is contained within a piece that is separate from the front cover and the rear cover and is attachable to either the front cover or the rear cover.

16. The device according to claim 7 wherein the electronic circuit is contained within a piece that is separate from the front cover and the rear cover and is attachable to either the front cover or the rear cover.

17. The device according to claim 8 wherein the electronic circuit is contained within a piece that is separate from the front cover and the rear cover and is attachable to either the front cover or the rear cover.

18. The device according to claim 9 wherein the electronic circuit is contained within a piece that is separate from the front cover and the rear cover and is attachable to either the front cover or the rear cover.
